(19) United States
(12) Patent Application Publication
(10) Pub. No.: US 2012/0326701 A1
(43) Pub. Date: Dec. 27, 2012

(54) Configurable Process Variation Monitoring Circuit of Die and Monitoring Method Thereof

(75) Inventors: YING-YEN CHEN, Chia Yi County (TW); Jih-Nung Lee, Hsin Chu County (TW)

(73) Assignee: Realtek Semiconductor Corp.

(21) Appl. No.: 13/452,383

(22) Filed: Apr. 20, 2012

(30) Foreign Application Priority Data
Apr. 26, 2011 (TW) 100114380

(51) Int. Cl. G01R 23/02; H01L 27/06

(52) U.S. Cl. 324/76.12; 257/48; 257/E27.013

(57) ABSTRACT

The present invention discloses a configurable process variation monitoring circuit of a die and monitoring method thereof. The monitoring method includes a ring oscillator, a frequency divider and a frequency detector. The ring oscillator includes a plurality of first standard cells, a plurality of second standard cells and a plurality of multiplexers. The ring oscillator generates an oscillation signal in a first mode or a second mode according to a selection signal. The frequency divider is coupled to the ring oscillator and divides the oscillation signal by a value to generate a divided signal. The frequency divider is coupled to the frequency divider and counts periods of the divided signal by a base clock to generate an output value where the output value is related to the process variation.

### BACKGROUND OF THE INVENTION

(a) Field of the Invention

The invention relates to a process variation monitoring circuit, particularly to a configurable process variation monitoring circuit of die and the monitoring method thereof.

(b) Description of the Related Art

As the CMOS (complementary metal oxide semiconductor) process keeps advancing to the nanometer era, the influence of process variation on product becomes greater and thus increases difficulty in yield ramp-up. Traditionally, the low yield problem is diagnosed by using a defect diagnosis tool which generally focuses on finding defect locations based on a static fault model. However, a static fault model used in diagnosis cannot precisely simulate the effect caused by the process variation.

A method to obtain process information is to dispose a test key in scribe lines of a wafer implemented by the wafer foundry to collect process related information, but the number of test keys disposed in a wafer is limited due to area cost concerns. Besides, the layout pattern around a test key is quite different from that around functional logics. That means the layout dependent process variation cannot be observed using a wafer test key. Further these test keys cannot be preserved after wafer dicing. To promote the subsequent diagnostic or debugging capability for effectively improving the product yield, more process information is required to acquire through other methods.

Another method is to use monitoring circuits built in a chip but these circuits are generally designed as analog circuits in order to have high accuracy. The configuration of an analog circuit is different from that of a digital circuit. Because of custom design, an analog circuit can tolerate larger process variation. Thus the influence of process variation on the digital circuit cannot be clearly reflected.

After a wafer is back to a factory, generally the wafer should be analyzed on its yield to find out the current process condition. A common analysis method is to use a wafer map to understand process status and such a method needs to measure each test key but the test machine is very expensive during the CP/FT mass production testing phase. The testing time of this method is long and thus the testing cost is very expensive.

Current methods for collecting process information require measurement equipment or testing machines to measure signal parameters. Thus, not only is high-end measurement equipment required, but the equipment itself may introduce an error. Besides, the size of IC elements decreases with the advance of processes and the speed also increases at the same time. At the time, the delay caused by metal wires is relatively apparent. Therefore, the influence of the variation of metal wires on the circuit speed becomes non-negligible but the current method cannot measure the variation of metal wires resulting in the problem of poor diagnosis.

### BRIEF SUMMARY OF THE INVENTION

One object of the invention is to provide a configurable process variation monitoring circuit of a die.

One object of the invention is to provide configurable monitoring method for detecting process variation effects on a die.

According to the invention, a configurable process variation monitoring circuit of die comprises a ring oscillator, a frequency divider and a frequency detector. The ring oscillator comprises a plurality of first standard cells, a plurality of second standard cells and a plurality of multiplexers and generates an oscillation signal in a first mode or a second mode according to a selection signal. The frequency divider is coupled to the ring oscillator and divides the oscillation signal by a divisor value to generate a divided signal. The frequency detector is coupled to the frequency divider and counts periods of the divided signal by a base clock to generate an output counting value. The output counting value is related to process variation of the die.

According to the invention, a configurable process variation monitoring method of a die comprises the following steps: switching a ring oscillator to generate an oscillation signal in a first mode or a second mode according to a selection signal; dividing the oscillation signal by a divisor value to generate a divided signal; and counting periods of the divided signal by a base clock to generate an output counting value; wherein the ring oscillator comprises a plurality of first standard cells, a plurality of second standard cells and a plurality of multiplexers and the output counting value is related to process variation of the die.

Other objects and advantages of the invention can be better understood from the technical characteristics disclosed by the invention. In order to clarify the above mentioned and other objects and advantages of the invention, examples accompanying with figures are provided and described in details in the following.

### BRIEF DESCRIPTION OF THE DRAWINGS

FIG. 1 shows a block diagram illustrating a configurable process variation monitoring circuit of a die according to a first embodiment of the invention;

FIG. 2 shows a circuit diagram illustrating a ring oscillator according to one embodiment of the invention;

FIG. 3 shows a block diagram illustrating a configurable process variation monitoring circuit of a die according to a second embodiment of the invention;

FIG. 4 shows a circuit diagram illustrating a ring oscillator according to another embodiment of the invention;

FIG. 5 show a flow chart illustrating a configurable process variation monitoring method of a die according to one embodiment of the invention; and

FIG. 6 show a flow chart illustrating a configurable process variation monitoring method of a die according to another embodiment of the invention.

### DETAILED DESCRIPTION OF THE INVENTION

The invention provides a configurable process variation monitoring circuit of a die and a monitoring method thereof to show the whole process variation carried by the monitoring circuit for subsequent diagnosis monitoring circuit completely by digital circuit design. By configurable setting, the time requirement of mass production testing can be matched, dies with bad quality or being greatly negatively influenced by processes can be quickly sorted out, and distinguishability can be maintained in a high state.

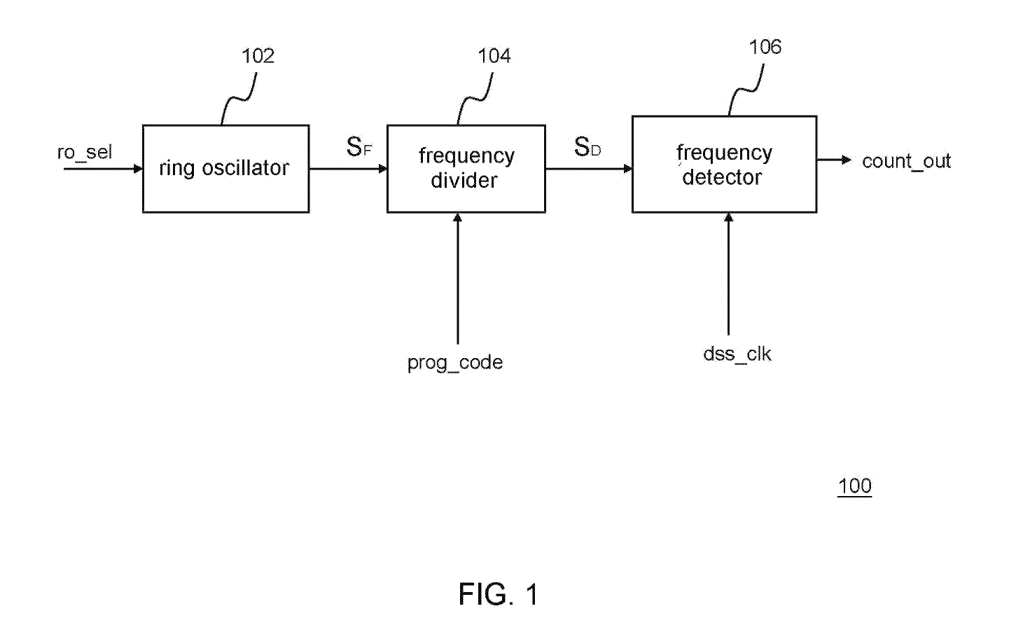

FIG. 1 shows a block diagram illustrating a configurable process variation monitoring circuit of a die according to a first embodiment of the invention. The ring oscillator 102 includes an oscillation path, formed by a plurality of different standard cells in series connection, and is configurable according to the path selection signal ro_sel to generate an oscillation signal S_{F} through different oscillation paths. The frequency divider 104 divides the oscillation signal S_{F} according to an input command prog_code and converts the high-frequency oscillation signal S_{F} into a low-frequency divided signal S_{D}. The frequency detector 106 detects periods of the divided signal S_{D} by a clock signal dss_clk to generate an output counting value count_out. The process variation monitoring circuit 100 can be disposed at any location in the chip and preferably is disposed in the timing critical or power critical area.

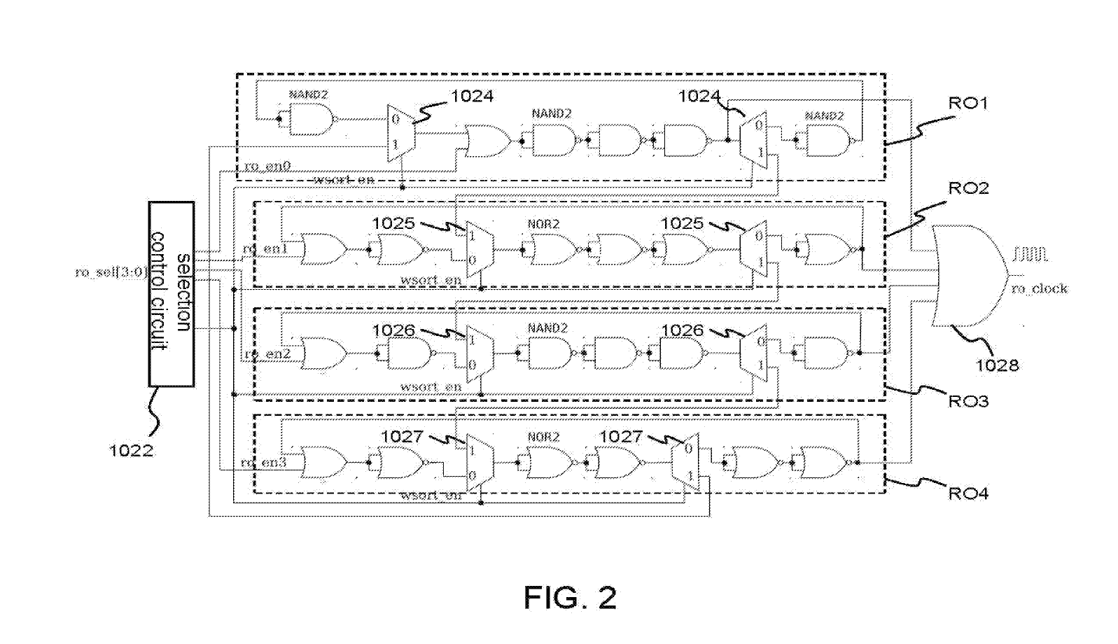

FIG. 2 shows a circuit diagram of a ring oscillator according to an embodiment of the invention. The ring oscillator is formed by a plurality of oscillation paths, for example four oscillation paths. Each ring oscillation path is formed by the same type of standard cells and is designed to be configurable to provide either a single-cell type mode or a mixed-cell type mode. The standard cells are referred to standard logic cells provided by a wafer foundry, such as NAND gates, NOR gates, etc. In this embodiment, the first path RO1 is formed by a plurality of inverters NAND2 connected in series where the inverters are formed by NAND gates. The first path RO1 is coupled between the selection control circuit 1022 and the OR gate 1028 via the multiplexer 1024. The third path RO3 is the same as the first path RO1. The second path RO2 is formed by a plurality of inverters NOR2 connected in series where the inverters are formed by NOR gates. The second path RO2 is coupled between the selection control circuit 1022 and the OR gate 1028 via the multiplexer 1025. The fourth path RO4 is the same as the second path RO2. The selection control circuit 1022 generates path enabling signals ro_en0˜ro_en3 and a multiplexer enabling signal wsort_en in different modes according to the selection signal ro_sel.

For example, in the single-cell type mode, the first path RO1, the second path RO2, the third path RO3 or the fourth path RO4 is enabled and the oscillation clock ro_clock, that is, oscillation signal S_{F} in FIG. 1, generated by a different path is outputted via the OR gate 1028. Further the frequency detector 106 generates four counting values corresponding to each path. In the mixed-cell type mode, the path enabling signals ro_en0˜ro_en3 enable the first path RO1, the second path RO2, the third path RO3 and the fourth path RO4 and the multiplexer enabling signal wsort_en is used to switch the multiplexers 1024˜1027 to change oscillation paths. The oscillation clock ro_clock having a mixed-cell property is outputted from the output end of the OR gate 1028 via the first path RO1—the fourth path RO4. In another embodiment, the OR gate 1028 can be implemented by a multiplexer.

The oscillation signal S_{F} and its counting value generated in a different mode can be used differently. For example, in the single-cell type mode, the counting value includes simpler process variation. The counting value generated via the first path RO1 is only related to the process variation related to NAND gates. Thus, according to the information of NAND gates provided by a standard cell library, for example, the delay caused by each NAND gate, the divisor value for the frequency divider 104 can be properly set, accordingly. The counting value generated by the frequency detector 106 can be compared with an expected result and the degree of delay shown by the counting value can be determined whether or not to be within a tolerable range. Therefore, the information of process variation in the same process for different standard cells can be provided. During debugging or diagnosis, detailed information can be provided. For example, during diagnosis, generally more time is taken to do measurement and distinguishable information is required to determine whether the low yield problem comes from the process, circuit design or design process defect. Therefore, during diagnosis, the process variation monitoring circuit of FIG. 1 can be switched to the single-cell type mode to distinguish whether there is cell-dependent or device-dependent variation.

This embodiment designs the first path RO1 and the third path RO3 to use the same standard cells and thus the output counting values from the first path RO1 and the third path RO3 can be compared against each other to collect the information related to process stability. The output counting value generated in the mixed-cell type mode has a property of mixing various types of standard cells and this cannot provide detailed process variation but in this mode the oscillation signal including different standard cell properties can be generated fast. Therefore, the mixed-cell type mode is suitable to the situation under time pressure. For example, a mass production testing phase requires quickly grading chips to have a standard for chip sorting.

In another embodiment, the single-cell type mode can arrange a preset order for selecting paths to output oscillation clock and repeat to operate the selection as a cycle. For example, firstly the first path RO1 outputs the oscillation clock ro_clock, then the third path RO3 outputs the oscillation clock ro_clock, and then the second path RO2 outputs the oscillation clock ro_clock, etc. The mixed-cell type mode can also include various types. For example, only the first path RO1 and the second path RO2 output the oscillation clock ro_clock.

The inherent characteristic information of standard cells such as timing, power, delay, noise, etc., can be found from the standard cell library provided by the wafer foundry. Therefore, according to the selected path and the standard cell library, the input command prog_code determines the divisor value for the frequency divider 104 to divide the oscillation signal S_{F} so that the clock signal dss_clk can correctly count periods of the divided signal S_{D} to generate good resolution.

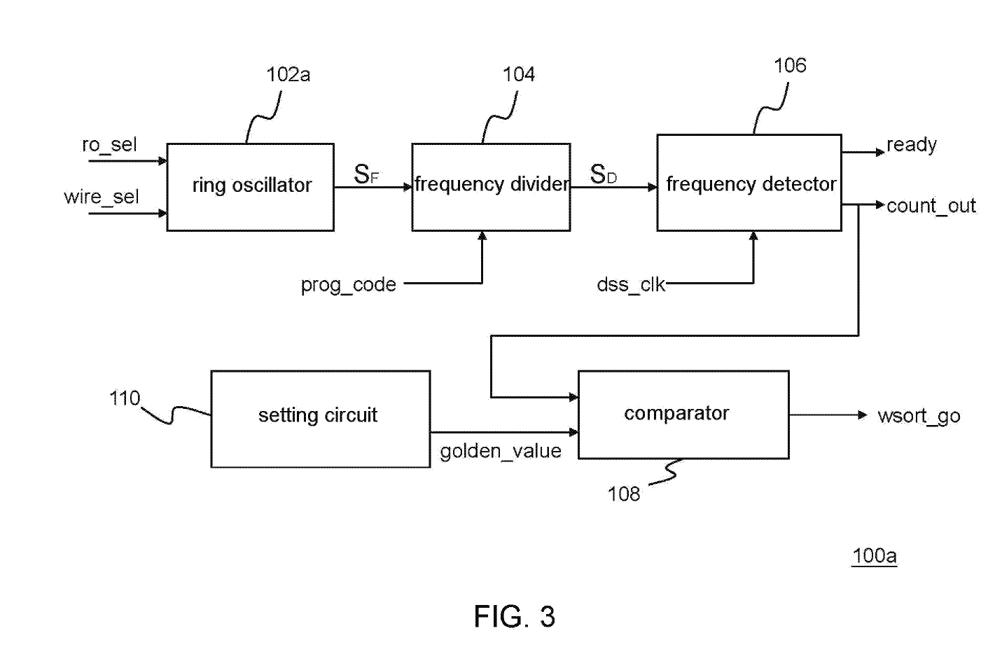

FIG. 3 shows a block diagram illustrating a configurable process variation monitoring circuit of a die according to an embodiment of the invention. In the process variation monitoring circuit 100a, the ring oscillator 102 includes a plurality of oscillation paths which can be selected according to the path selection signal ro_sel and the wire selection signal wire_sel to switch the path to generate the oscillation signal S_{F}. The frequency divider 104 divides the oscillation signal S_{F} to generate the divided signal S_{D}. The frequency detector 106 receives the divided signal S_{D} and generates the output counting value count_out. The comparator 108 compares the output counting value count_out with the standard counting value golden_value to generate a sorting signal wsort_go. Since the test machine is very expensive and it is used during CP/FT mass production testing phase, the test time should be reduced as much as possible to reduce the testing cost. Therefore, the CP/FT mass production test can choose using the mixed-cell type mode for testing to reduce the number of testing times. The output counting value count_out is compared with the standard counting value golden_value to generate the sorting signal wsort_go for sorting out the current tested chip. For example, when the output counting value count_out is larger than the standard counting value golden_value, the current tested chip is eliminated. The standard counting value golden_value is determined by the setting circuit 110. In an embodiment, the setting circuit 110 may include a user interface for a user to input the standard counting value golden_value. In another embodiment, during post-layout simulation, a look-up table is complete and stored in the setting circuit 110. According to the selected mode and path, the setting circuit 110 selects a corresponding standard counting value golden_value from the look-up table to supply to the comparator 108. In another embodiment, a plurality of sets of standard counting values can be designed to sort out the tested chips more precisely.

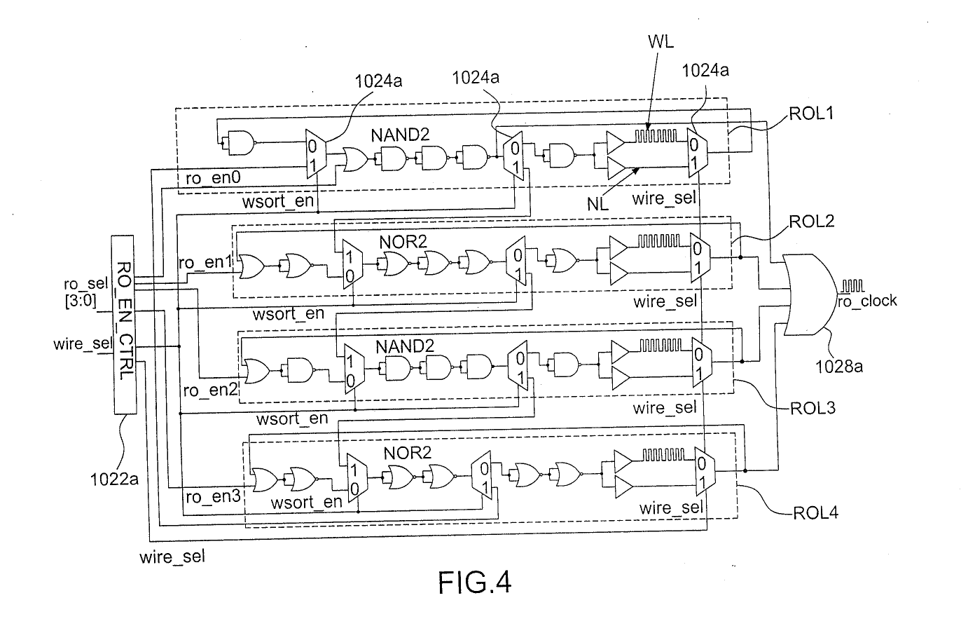

FIG. 4 shows an embodiment of the ring oscillator 102a. In the ring oscillator 102a, the first path ROL1 includes a plurality of inverters NAND2 formed by NAND gates, a long wire path W_{L}, a normal wire path W_{N} and three multiplexers 1024a. The second path ROL2, the third path ROL3 and the fourth path ROL4 separately include a long wire path, a normal wire path and corresponding multiplexers. In order to avoid the figure become too complex, only the first path ROL1 is labeled. The ring oscillator 102a of this embodiment includes eight oscillation paths. Therefore, according to the setting of the path selection signal ro_sel and the wire selection signal wire_sel, the selection control circuit 1022 uses the path enabling signals ro_en0˜ro_en3 to enable different paths. In the single-cell type mode and the mixed-cell type mode, further a long wire mode or a normal wire mode can be selected to output the oscillation signal ro_clock accompanying with the multiplexer enabling signal wsort_en and the wire selection signal wire_sel. For example, when the path enabling signals ro_en0 equals to 1′b1, the multiplexer enabling signal wsort_en equals to 1′b0, and the wire selection signal wire_sel equals to 1′b0, the signal transmission path passes through the long wire path W_{L}. Therefore, the variation of the metal wire affects the periods of oscillation. Further through the observation of variation of oscillation periods, an effect of the variation of the metal wire on the process can be determined. When the multiplexer enabling signal wsort_en equals to 1′b1, the signal transmission path passes through the normal wire path W_{N}. Under this mode, the signal propagation delay is determined by device delay.

When the multiplexer enabling signal wsort_en=1′b1, the signal transmission path passes through four oscillation paths to generate the oscillation signal ro_clock in the mixed-cell type mode. Therefore, delay caused by different cells affects the final result and the speed of the tested chip can be quickly determined to reach the standard or not.

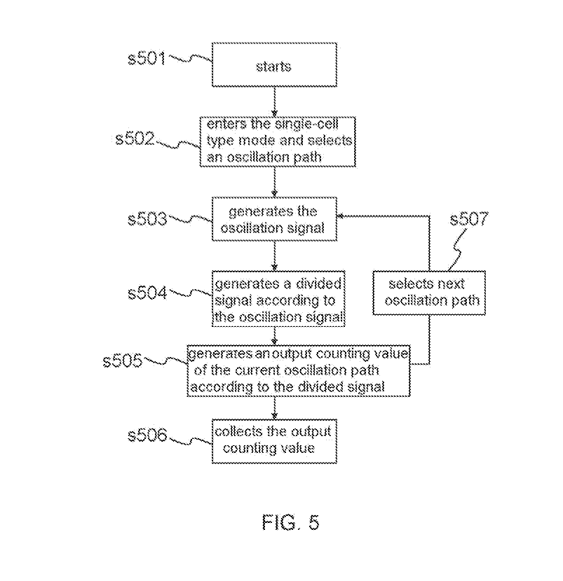

FIG. 5 show a flow chart illustrating a configurable process variation monitoring method of a die according to one embodiment of the invention. Please refer to FIG. 1. After step S501 starts, the ring oscillator 102 is in the single-cell type mode in step S502 to select an oscillation path. In step S503, the oscillation path generates the oscillation signal S_{F}. In step S504, the frequency divider 104 divides the oscillation signal to generate a divided signal S_{D}. In step S505, the frequency detector 106 detects periods of the divided signal S_{D} to generate an output counting value count_out of the current oscillation path. In step S507, next oscillation path is selected to go back to step S503. The output counting value count_out is outputted in step S506 to be collected by back-end circuits for diagnosis or debugging.

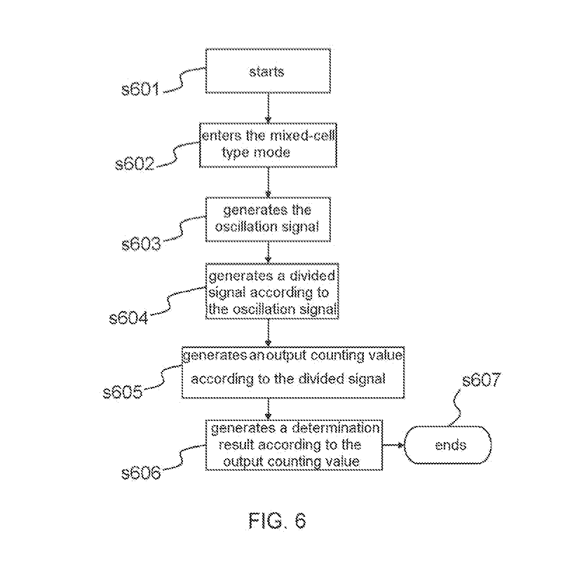

FIG. 6 show a flow chart illustrating a configurable process variation monitoring method of a die according to another embodiment of the invention. Please refer to FIG. 3 and FIG. 6. After step S601 starts, the ring oscillator 102a is in the mixed-cell type mode in step S602. In step S603, the mixed path generates the oscillation signal S_{F}. In step S604, the frequency divider 104 divides the oscillation signal S_{F} to generate a divided signal S_{D}. In step S605, the frequency detector 106 detects periods of the divided signal S_{D} to generate an output counting value. In step S606, the comparator 108 compares the output counting value count out with the standard counting value golden_value to generate a determination result, for example, determining whether or not to eliminate the current test chip to enter step S607: end.

The process variation monitoring circuit according to the invention can be disposed in different areas of the chip to acquire the information of intra-die process variation and also be disposed in different chips of the same wafer to acquire the information of inter-die process variation. Furthermore, the process variation monitoring circuit according to the invention can be disposed in the same area of different wafers to acquire the information of cross-wafer process variation. The variation of the location of the process variation monitoring circuit and the information collected by the output values can be expected. Various modifications or changes can be made by those who are skilled in the art without deviating from the spirit of the invention. Any embodiment or claim of the present invention does not need to reach all the disclosed objects, advantages, and uniqueness of the invention. Besides, the abstract and the title are only used for assisting the search of the patent documentation and should not be construed as any limitation on the implementation range of the invention. Although the present invention has been fully described by the above embodiments, the embodiments should not constitute the limitation of the scope of the invention.

What is claimed is:

1. A configurable process variation monitoring circuit of a die, comprising:
a ring oscillator, comprises a plurality of first standard cells, a plurality of second standard cells and a plurality of multiplexers, generating an oscillation signal in a first mode or a second mode according to a selection signal;
a frequency divider, coupled to the ring oscillator, dividing the oscillation signal by a divisor value to generate a divided signal; and
a frequency detector, coupled to the frequency divider, counting periods of the divided signal by a base clock to generate an output counting value;
wherein the output counting value is related to process variation of the die.

2. The circuit according to claim 1, wherein the ring oscillator comprises:
a first path, comprising a plurality of first multiplexers and a plurality of first inverters formed by the first standard cells;
a second path, comprising a plurality of second multiplexers and a plurality of second inverters formed by the second standard cells;
a selection control circuit, coupled to the first path and the second path, enabling the first path, the second path or the first path and the second path according to the selection signal; and
a third multiplexer, coupled among the first path, the second path and an output end.

3. The circuit according to claim 2, wherein the first path and the second path separately comprise a long wire path and a normal wire path.

4. The circuit according to claim 3, further comprising:
a fourth multiplexer, controlled to switch between having the oscillation signal generated by the long wire path and having the oscillation signal generated by the normal wire path.

5. The circuit according to claim 2, wherein the oscillation signal is generated through the first path or the second path in the first mode and is generated through the first path and the second path in the second mode.

6. The circuit according to claim 5, wherein the divisor value is related to the first standard cell or the second standard cell in the first mode and is related to the first standard cell and the second standard cell in the second mode.

7. The circuit according to claim 1, wherein the ring oscillator, the frequency divider and the frequency detector are disposed on the die.

8. The circuit according to claim 1, further comprising:
a setting circuit, providing a standard counting value; and
a comparator, comparing the output counting value with the standard counting value to generate a sorting signal;
wherein the sorting signal is used to determine a grade of the die.

9. The circuit according to claim 8, wherein the setting circuit comprises a user interface and a register.

10. The circuit according to claim 1, wherein the first standard cells are NAND gates and the second standard cells are NOR gates.

11. A configurable process variation monitoring method of a die, comprising:
switching a ring oscillator to generate an oscillation signal in a first mode or a second mode according to a selection signal;
dividing the oscillation signal by a divisor value to generate a divided signal; and
counting periods of the divided signal by a base clock to generate an output counting value;
wherein the ring oscillator comprises a plurality of first standard cells, a plurality of second standard cells and a plurality of multiplexers, and the output counting value is related to process variation of the die.

12. The method according to claim 11, wherein the ring oscillator comprises:
a first path formed by a plurality of first multiplexers and the first standard cells;
a second path formed by a plurality of second multiplexers and the second standard cells;
a selection control circuit, coupled to the first path and the second path and enabling the first path, the second path or the first path and the second path according to the selection signal; and
a third multiplexer, coupled among the first path, the second path and an output end.

13. The method according to claim 12, wherein the first path and the second path separately comprise a long wire path and a normal wire path.

14. The method according to claim 13, further comprising:
a fourth multiplexer, controlled to switch between having the oscillation signal generated by the long wire path and having the oscillation signal generated by the normal wire path.

15. The method according to claim 12, wherein the step of switching a ring oscillator to generate an oscillation signal in a first mode or a second mode according to a selection signal further comprises:
generating the oscillation signal through the first path or the second path in the first mode; and
generating the oscillation signal through the first path and the second path in the second mode.

16. The method according to claim 15, wherein the step of dividing the oscillation signal by a divisor value to generate a divided signal further comprises:
determining the divisor value according to delay data of the first standard cell or the second standard cell in a standard cell library in the first mode; or
determining the divisor value according to delay data of the first standard cell and the second standard cell in the standard cell library in the second mode.

17. The method according to claim 11, further comprising:
providing a standard counting value;
comparing the output counting value with the standard counting value to generate a sorting signal; and
determining a grade of the die according to the sorting signal.

18. The method according to claim 11, wherein the first standard cells are NAND gates and the second standard cells are NOR gates.
